(19) United States
(12) Patent Application Publication
(10) Pub. No.: US 2008/0061809 A1
(43) Pub. Date: Mar. 13, 2008

(54) POGO PINS AND CONTACT-TYPE OF TEST DEVICE HAVING POGO PINS FOR TESTING SEMICONDUCTOR DEVICE

(75) Inventors: Sang-jun LEE, Cheonan-si (KR); Ho-gyung KIM, Cheonan-si (KR); Jae-ho SONG, Cheonan-si (KR); Tae-gyu KIM, Cheonan-si (KR); Ho KIM, Cheonan-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/760,930

(22) Filed: Jun. 11, 2007

(30) Foreign Application Priority Data
Sep. 8, 2006 (KR) 10-2006-0086996

(51) Int. Cl. G01R 1/073; G01R 1/067

(52) U.S. Cl. 324/761

(57) ABSTRACT

A pogo pin of a contact-type of semiconductor test device will not be oxidized and will not damage of a solder ball of a semiconductor package when the pogo pin is brought into contact with the solder ball. The pogo pin includes an electrical contact of a conductive rubber material, and a spring extending from the bottom of the electrical contact. The test device includes an array of the pogo pins, and a housing that supports the array of pogo pins. The housing may include detachable members between which the pogo pins are interposed such that the pogo pins can be individually replaced.

### BACKGROUND OF THE INVENTION

1. Field of the Invention

The present invention relates to equipment for testing semiconductor devices. More particularly, the present invention relates to a contact-type of testing device for testing the electrical performance of a semiconductor device.

2. Description of the Related Art

Electrical properties of chips on a wafer are tested by an electrical die sorting (EDS) process before the chips are packaged. Electrical properties of semiconductor packages which comprise the chips are also tested. The tests basically verify whether semiconductor devices of the chips meet certain performance criteria. In recent years, a contact-type of testing device having probes, known as pogo pins, has been widely used for testing highly integrated semiconductor devices The pogo pins of the contact-type of testing device electrically connect a semiconductor device to be tested with a test board or device under testing (DUT).

FIGS. 1 and 2 illustrate a conventional contact-type of test device for testing semiconductor devices. Referring to FIG. 1, the test device includes pogo pins 10, a housing 30 for supporting the pogo pins 10, and a contactor board 40 disposed beneath the housing 30. Each pogo pin 10, as shown in FIG. 2, has a plunger 12, a barrel 14 in which the plunger 12 is supported so as to be extendable and retractable relative to the barrel 141 and a spring disposed within the barrel 14 for biasing the plunger 12 to an extended position. The barrel 14 of each pogo pin 10 is held in place in a respective guide passageway 20 of the housing 30. The plunger 12 of each pogo pin 10 has a crown-shaped head A.

Terminals, e.g., solder balls, of a semiconductor package 50 are brought into contact with the crown-shaped heads A of the plungers 12 to initiate a testing of the devices of the semiconductor package 50. FIG. 3A shows a solder ball 60 of the semiconductor package before the solder ball 60 is brought into contact with the crown-shaped head A of a plunger 12. In the semiconductor package shown in FIG. 3A, two semiconductor chips 70 are stacked on a package substrate 80, and the solder ball 60 is disposed beneath the package substrate 80 and is electrically connected to the chips 70. The solder ball 60 serves to electrically connect the semiconductor package to external circuitry, such as that of a main circuit board. Note, in the present specification and claims that follow, the term “semiconductor package” will refer to all types of products having semiconductor devices and external terminals that can be tested using a contact-type of test device.

In the conventional contact-type of test device, however, the crown-shaped head A of a pogo pin 10 can damage a solder ball 60 of the semiconductor package, as shown in FIG. 3B. This increases the resistance of the solder ball or prevents the solder ball from sufficiently making contact with the main circuit board, for example. Accordingly, the semiconductor package must often be discarded after it is tested with the conventional contact-type of test device.

Furthermore, the solder ball 60 is generally formed of an alloy of lead and tin. The lead component of the solder ball 60 can cause gold plating of the pogo pin 10 to peel off of a surface of the pogo pin. In addition, the gold plating often peels off of a surface of the pogo pin due to friction between the plunger 12 and the barrel 14 when the plunger 12 reciprocates or vibrates within the barrel 14. In either of these cases, the exposed surface of the pogo pin will oxidize. The oxidization is particularly severe at the upper portion of the pogo pin brought into contact with the solder ball.

Accordingly, the resistance of the pogo pin increases, which impedes the transmittance of electrical signals through the pogo pin and thus affects the efficiency of the signal processing carried out by the test apparatus. Therefore, the pogo pin must be replaced whenever one of the above-described defects occurs. That is, the conventional contact-type of test device requires frequent repair. A conventional pogo pin, though, is expensive because it includes a plunger, a barrel, and a spring. Thus, the use of the conventional contact-type of test device imposes additional costs on the manufacturing of semiconductor packages. Another problem with the conventional pogo pins is that the elasticity of their steel springs is low when the temperature is about −10° C. or lower and especially when the temperature is in a range of about −5 to about −25° C. Thus, at these temperatures, the plungers of the pogo pins will not sufficiently extend and retract and hence, the pogo pins will not contact the terminals of the semiconductor package sufficiently.

A contact-type of test device having pogo pins consisting of a column of electrically conductive rubber material has been proposed as a way to solve the above-described problems. However, the rubber material does not sufficiently absorb shock when the pogo pins are brought into contact with the solder balls. Accordingly, the solder balls may be deformed or the package may be otherwise damaged. Furthermore, the pogo pins are formed so as to be unitary with the housing of the test device. Therefore, the contact-type of test device must be replaced in its entirety even when only one of the pogo pins is defective.

### SUMMARY OF THE INVENTION

An object of the present invention is to provide a pogo pin which will not damage a semiconductor package when brought into contact with the package.

A more specific object of the present invention is to provide a pogo pin which will not damage a solder ball of a semiconductor package when brought into contact with the solder ball.

Another object of the present invention is to provide a pogo pin whose outer surface will not be oxidized especially when the pogo pin is brought into contact with a solder ball.

Another object of the present invention is to provide a contact-type of semiconductor test device having pogo pins which function effectively at room temperature or below.

Still another object of the present invention is to provide a contact-type of semiconductor test device having pogo pins that can be replaced individually or whose parts can be replaced individually.

According to an aspect of the present invention, there is provided a pogo pin including an electrical contact formed of an electrically conductive rubber material, and a spring extending from a bottom of the contact. The top of the electrical contact may be a contact pad of electrically conductive silicon rubber, and the bottom of the electrical contact may be a rigid plunger of electrically conductive material. The contact pad may include gold-plated metal particles. Furthermore, the spring may be a helical spring, in which case the spring is preferably formed of a gold-plated metal wire. The conductive plunger is preferably a gold-plated columnar member.

According to another aspect of the present invention, there is provided a contact-type of test device including an array of pogo pins, and a housing supporting the array of pogo pins each including an electrical contact and a spring extending from the bottom of the electrical contact, and characterized in that the top of the electrical contact is exposed at an upper portion of the housing and is formed of electrically conductive rubber material.

The housing may have guide passageways in which the pogo pins are disposed, respectively. The pogo pins are supported by the housing such that the pogo pins can reciprocate within the guide passageways. Preferably, the housing includes detachable members between which the pogo pins are interposed, such that the pogo pins can be replaced individually when the members of the housing are detached from one another. In particular, the housing may include an upper housing member having guide opening extending therethrough, and a lower housing member having through-holes aligned with the guide openings. The electrical contacts of the pogo pins are received in the guide openings of the upper housing member, and the springs of the pogo pins are received in the through-holes of the lower housing member. Preferably, bottom portions of the springs are press-fitted to the lower housing member.

### BRIEF DESCRIPTION OF THE DRAWINGS

The above and other objects, features and advantages of the present invention will become more apparent from the following detailed description of the preferred embodiments thereof made with reference to the attached drawings in which:

FIG. 1 is a cross-sectional view of a conventional contact-type of test device for testing a semiconductor device;

FIG. 2 is a perspective view of a pogo pin of the conventional test device;

FIG. 3A is a cross-sectional view of a semiconductor package of a type tested using the conventional contact-type of test device shown in FIG. 1;

FIG. 3B is a cross-sectional view of the semiconductor package after it has been tested using the conventional contact-type of test device and illustrates the damage to a solder ball of the package caused by a pogo pin of the test device;

FIG. 4 is a perspective view of a pogo pin according to the present invention;

FIG. 5A is a plan view of a contact-type of test device for testing semiconductor devices according to the present invention;

FIG. 5B is a bottom view of the contact-type of test device for testing semiconductor devices according to the present invention;

FIG. 5C is a sectional view of the contact-type of test device for testing semiconductor devices according to the present invention;

FIG. 5D is an enlarged view of portion B of the contact-type of test device shown in FIG. 5C; and

FIG. 5E is an exploded view of the contact-type of test device for testing semiconductor devices according to the present invention.

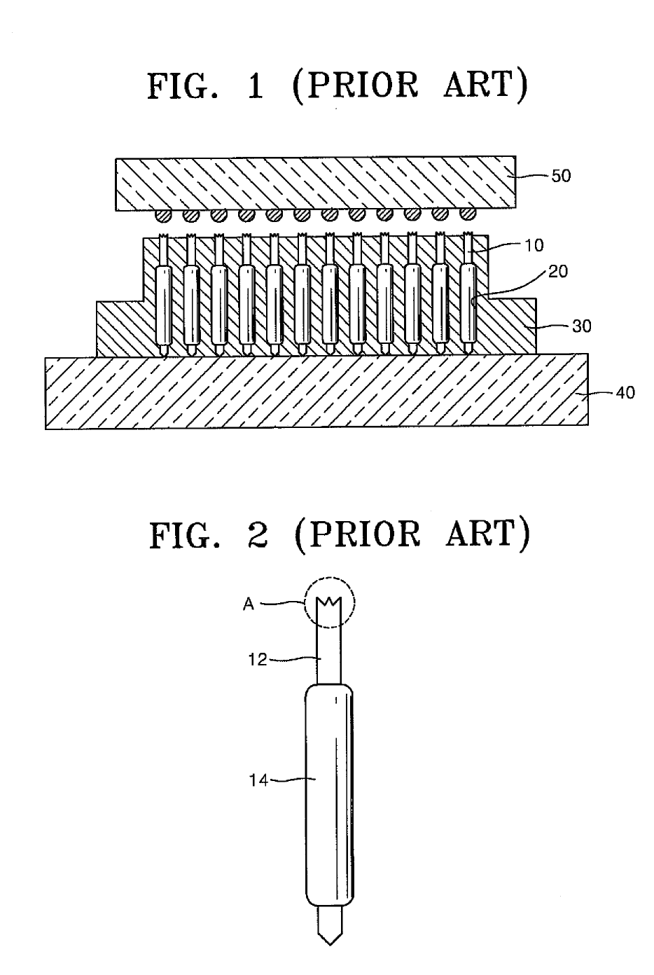

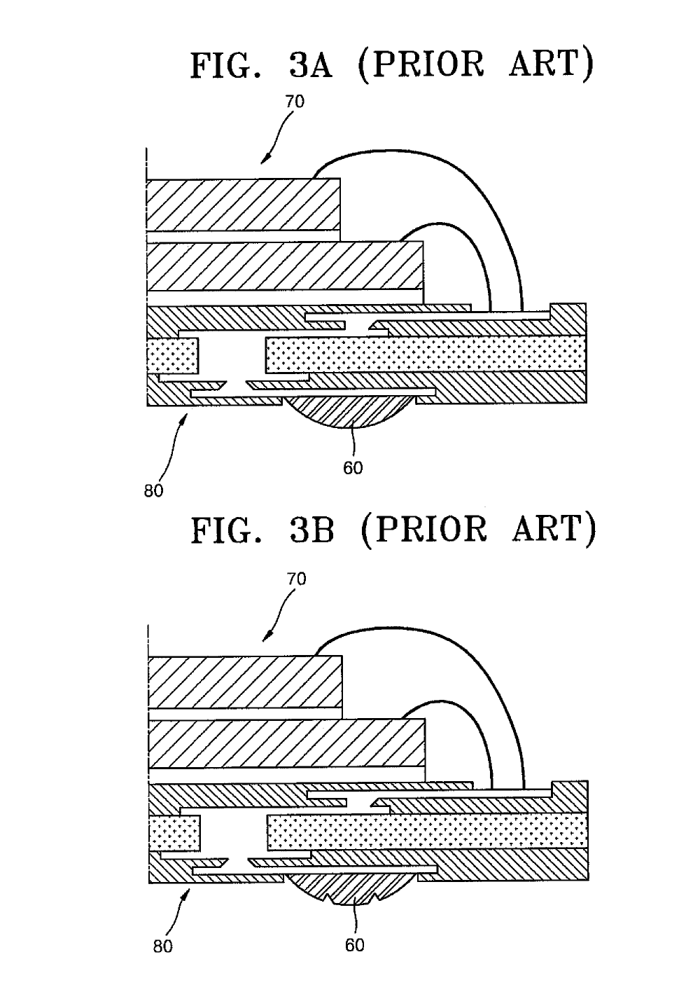

### DETAILED DESCRIPTION OF THE PREFERRED EMBODIMENTS

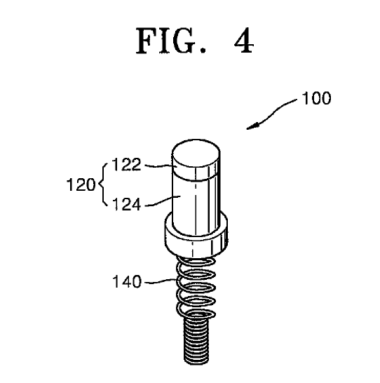

Referring to FIG. 4, a pogo pin 100 for use in a contact-type of testing device according to the present invention includes an electrical contact 120, and a spring 140 extending from the bottom of the contact 120. More specifically, the contact 120 includes a contact pad 122 at an upper portion thereof, and a plunger 124 at a lower portion thereof. The contact pad 122 is formed of a mixture of a silicon rubber and an electrically conductive material. The conductive material may be a gold-plated nickel powder. In this example, the silicon rubber and the nickel powder are mixed in a ratio of about 1:2 to 1:3. Specifically, the contact pad 122 may be formed by filling 70 to 80% of a cylindrical mold with gold-plated nickel powder, injecting a silicon rubber gel into the mold until the mold is full, mixing the gold-plated nickel powder and silicon rubber gel in the mold, and curing the silicon rubber gel.

The thickness of the contact pad 122 will depend on the structure of the semiconductor package to be tested. That is, the thickness of the contact pad 122 is designed such that the pad 122 will compress a certain amount given the elasticity of the underlying spring 140 and in consideration of the overall stroke that the pogo pin 100 must provide for effectively testing the semiconductor package. On the other hand, the diameter of the contact pad 122 depends on the size and layout of terminals, e.g., solder balls, of the semiconductor package to be tested. That is, the upper surface of the contact pad 122 preferably has a diameter greater than that of the corresponding solder ball of the semiconductor package so that the contact pad 122 will assuredly contact the solder ball. However, the solder balls of today's highly integrated semiconductor package are relatively small and have a relatively fine pitch. Therefore, the diameter of the contact pad 122 is most dependent on the layout of the solder balls of the semiconductor package.

The conductive plunger 124 of the contact 120 is formed by plating a columnar metal structure with gold. The conductive plunger 124 serves to mechanically and electrically connect the contact pad 122 with the underlying spring 140, i.e., to transmit forces and electrical signals between the contact pad 122 and the spring 140. The conductive plunger 124 must be carefully engaged with the contact pad 122 so as to be sufficiently coupled with the contact pad 122 and yet not prevent the contact pad 122 from sufficiently expanding and compressing when it is in use.

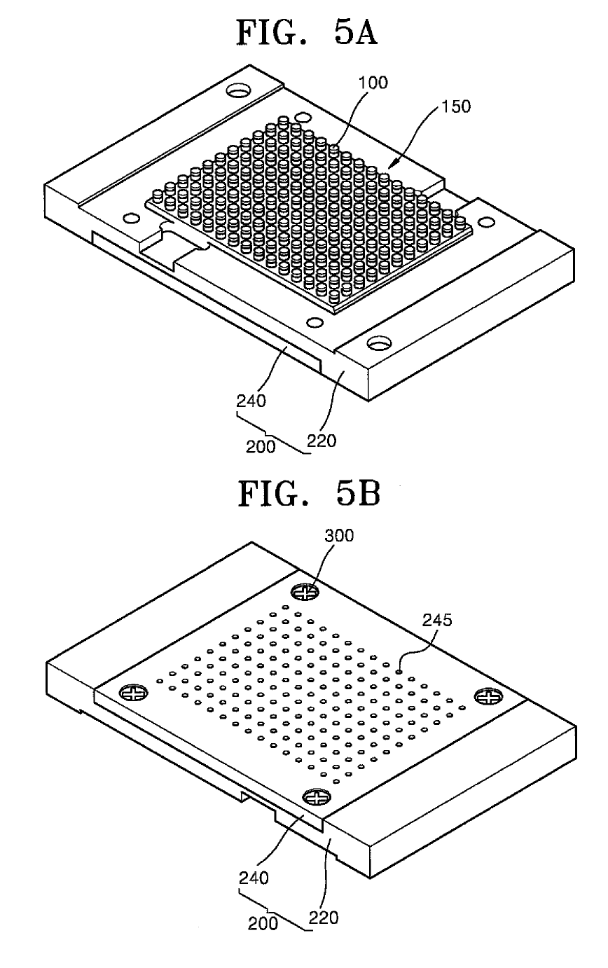

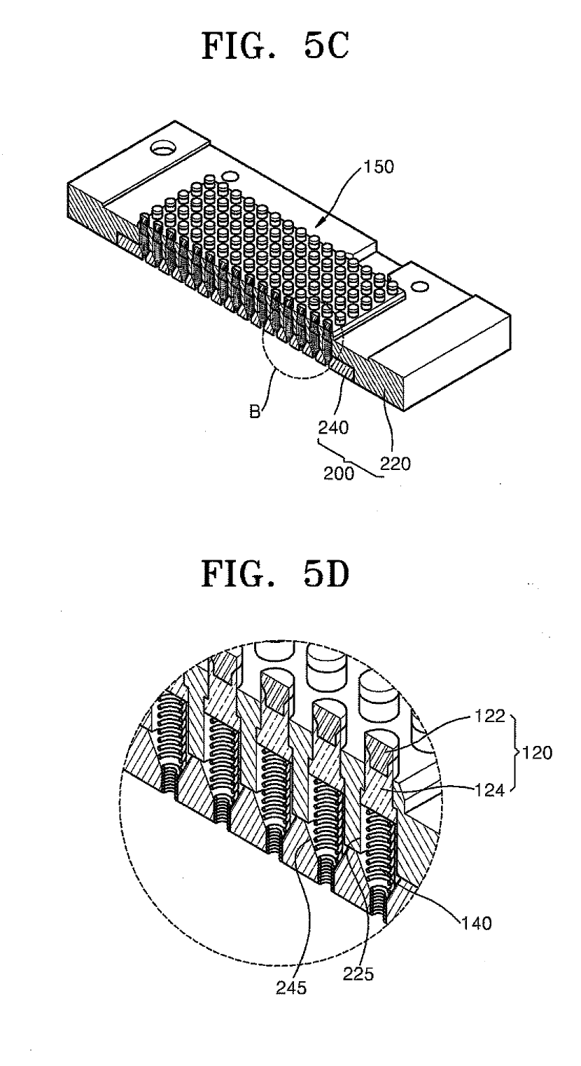

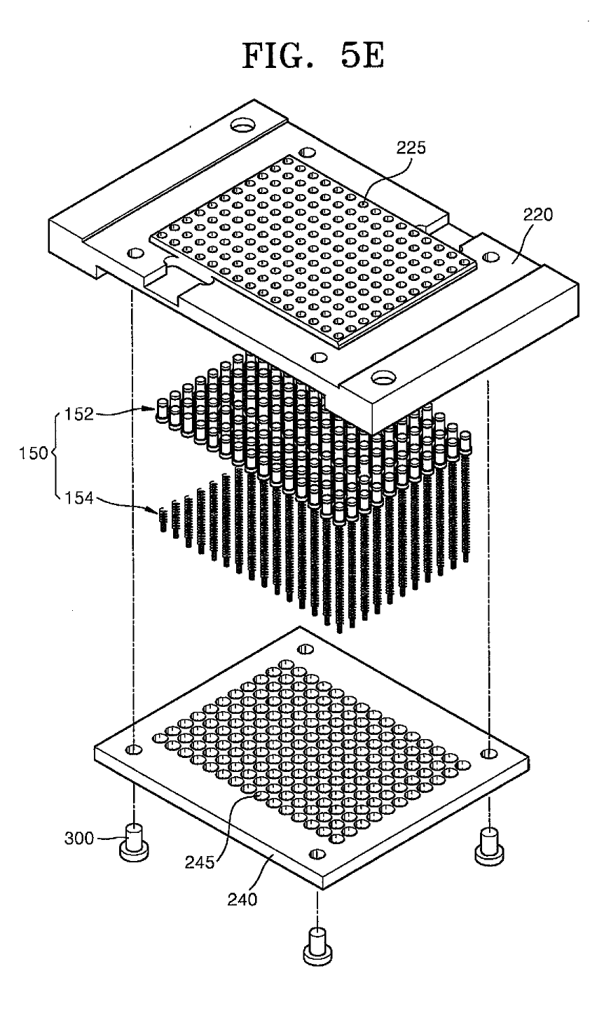

Preferably, both the contact pad 122 and the conductive plunger 124 are columnar and have circular cross sections, i.e., are both generally cylindrical. However, the contact pad 122 may alternatively have a square, triangular, or elliptical cross section. In any case, the shape of the conductive plunger 124 depends on the shape of the contact pad 122. In particular, the diameter of the upper portion of the plunger 124 may correspond to that of the contact pad 122, and the diameter of the lower portion of the plunger 124 may be greater than that of the upper portion to accommodate the upper portion of the spring 140. Also, the lower portion of the conductive plunger 124 serves to prevent the contact pad member 120 from falling out a guide opening 225 of an upper housing member of the test device, as will be described below in connection with FIGS. 5A-5E.

The spring 140 may be a helical (coil) spring formed of a steel wire. In this case, the spring 140 is plated with gold so that the spring will not be oxidized by a lead component of the solder ball and so as to facilitate the transmission of electrical signals at higher speeds. Alternatively, the spring 140 may be formed of a resilient material whose elasticity remains unchanged, particularly at a low temperature.

The stroke of a conventional pogo pin of the type shown in FIG. 2 corresponds only to the stroke of its spring while the stroke of a pogo pin 100 according to the present invention is a combination of both the compressibility of the contact pad 122 and the stroke of its spring 140. Thus, the present invention overcomes, to some extent, the drawback of the conventional pogo pin when used at temperatures of about −5 to about −25° C. In addition, the conventional pogo pin that consists of a column of electrically conductive rubber material can provide a stroke of at most 0.25 mm. Therefore, such a conventional pogo pin does not satisfactorily absorb shocks when placed in contact with the terminals, e.g., solder balls, of the semiconductor package during testing. On the other hand, a pogo pin according to the present invention can provide a stroke of 0.5 mm or more due to both the compressibility of its contact pad and its underlying spring. Thus, a pogo pin according to the present invention is sufficiently shock-absorbent and hence, can prevent a solder ball from being damaged or excessively impacted.

FIGS. 5A to 5E illustrate a contact-type of semiconductor test device according to the present invention. The test device includes a pogo pin array 150, and a housing 200 for supporting the pogo pin array 150. The pogo pin array 150 includes a plurality of rows and columns of pogo pins 100. The pogo pins 100 are to contact terminals, e.g., solder balls, of a semiconductor package to be tested.

The housing 200 includes an upper housing member 220 and a lower housing member 240. Each of the housing members 220 and 240 is rectangular and has holes for accommodating the pogo pins 100. The upper housing member 220 and the lower housing member 240 may be detachable. In this case, the pogo pins 100 of the pogo pin array 150 can be individually removed from the test device and replaced.

More specifically, as best shown in FIGS. 5B and 5E, the lower housing member 240 is detachably coupled to the upper housing member 220 by screws 300. The lower housing member 240 is smaller than the upper housing member 220 but can accommodate the pogo pins of the pogo pin array 150. The upper housing member 220 has a bottom surface whose central portion is recessed, at a central portion thereof, to accommodate the lower housing member 240. The depth of the recess may be identical to the thickness of the lower housing member 240, and the width of the recess may be identical to the width of the lower housing member 240. Accordingly, the bottom surface of the lower housing member 240 and the bottom surface of the upper housing member 120 are coplanar.

As best shown in FIGS. 5C and 5D, the housing 200 defines guide passageways in which the pogo pins of the pogo pin array 150 are disposed, respectively. Each passageway is made up of a guide opening 225 extending through the upper housing member 220, and a through-hole 245 in the lower housing member 240. The guide openings 225 serve to guide the pogo pins 100 such that the pogo pins 100 are movable relative to the housing 200 in the longitudinal direction of the passageways. The through-holes 245 in the lower housing member 240 accommodate bottom portions of the springs 140. In particular, the diameter of each through-hole 245 becomes smaller in a direction from top to bottom in the lower housing member 240. The lower ends of the springs 140 are press-fitted to the lower housing member 240 within bottom portions of the through-holes 245. The bottom portions of the through-holes 245 also allow the springs 140 to be electrically connected to an external test board.

Referring to FIG. 5D, the upper and lower portions of each guide opening 225 have different diameters. The lower portion of the guide opening 225 has a diameter that is substantially the same as that of the lower portion of the plunger 124 but is greater than that of the upper portion of the plunger 124 for allowing the spring 140 and the contact 120 to reciprocate inside the guide opening 225. The upper portion of the guide opening 225 has a diameter that is substantially the same as that of the upper portion of the plunger 124 but is smaller than that of the lower portion of the plunger 124 for preventing the lower portion of the plunger 124 from entering the upper portion of the guide opening 225. Thus, the guide opening 225 restricts the degree to which the contact 120 protrudes from the upper housing member 220.

FIG. 5E illustrates that the springs of the pogo pins do not have to be integral with the contacts. That is, the pogo pin array 150 may include an array of contacts 152 and an array of springs 154 corresponding to the contacts 152. The springs of the array 154 merely bear against the bottom surfaces of the contacts of the array 152, respectively. Therefore, if the contact of a pogo pin is defective, the contact can be replaced independently of the spring, and vice versa.

According to the present invention as described above, a pogo pin of a contact-type of semiconductor test device has a contact pad of an electrically conductive rubber material. Thus, the present invention will not damage the terminals (e.g., solder balls) of the package being tested, the pogo pins will not be affected by a lead component of solder balls of a package being tested, the test device can operate effectively at temperatures below room temperature, and the pogo pins facilitate the transmission of electrical signals at relatively high speeds. As a result, fewer semiconductor packages need to be discarded after being tested, and the test device itself has a relatively long useful life. In particular, the useful life of a test device according to the present invention is about two to three hundred thousand hours or more, whereas a comparable conventional contact-type of test device has a useful life of only one hundred thousand hours. Moreover, the pogo pins or parts thereof can be individually replaced according to the present invention. Therefore, the present invention can realize significant savings in connection with the costs of maintaining the device.

Finally, although the present invention has been described in connection with the preferred embodiments thereof, it is to be understood that the scope of the present invention is not so limited. On the contrary, various modifications of and changes to the preferred embodiments will be apparent to those of ordinary skill in the art. Thus, changes to and modifications of the preferred embodiments may fall within the true spirit and scope of the invention as defined by the appended claims.

What is claimed is:

1. A pogo pin for use in a contact-type of semiconductor test device, comprising:
an electrical contact having a top and a bottom, the top comprising electrically conductive rubber material; and
a spring extending from the bottom of the electrical contact.

2. The pogo pin of claim 1, wherein the electrical contact comprises a pad of an electrically conductive silicon rubber material at the top of the contact, and an electrically conductive rigid plunger at the bottom of the contact and to which the pad is attached.

3. The pogo pin of claim 2, wherein the pad comprises gold-plated metal particles.

4. The pogo pin of claim 2, wherein the spring is a coil spring, and the conductive plunger and the spring are gold-plated members.

5. The pogo pin of claim 2, wherein the plunger has an upper portion adjacent the pad and a lower portion adjacent the spring, and the diameter of the lower portion of the plunger is greater than the diameter of the upper portion of the plunger.

6. A contact-type of semiconductor test device, comprising:
a housing; and
an array of pogo pins supported by the housing, each of said pogo pins comprising an electrical contact having a top and a bottom, and a spring extending from the bottom of the electrical contact, wherein the top of the electrical contact of each of the pogo pins is exposed at an upper portion of the housing and comprises electrically conductive rubber material.

7. The test device of claim 6, wherein the springs of the pogo pins are press-fitted to the housing.

8. The test device of claim 7, wherein the electrical contact includes a contact pad of the electrically conductive silicon rubber material at the top of the contact, and an electrically conductive rigid plunger at the bottom of the contact and to which the pad is attached.

9. The test device of claim 8, wherein the pad comprises gold-plated metal particles.

10. The test device of claim 7, wherein the housing has guide passageways extending therethrough, and the pogo pins are disposed in the guide passageways, respectively, and are supported by the housing such that the pogo pins can reciprocate within the guide passageways.

11. The test device of claim 10, wherein the housing comprises detachable members between which the pogo pins are interposed, such that the pogo pins can be replaced individually when the members of the housing are detached from one another.

12. The test device of claim 11, wherein the springs of the pogo pins bear against bottom surfaces of the electrical contacts of the pogo pins, respectively, without being mechanically attached thereto, whereby the electrical contact and the spring of each of the pogo pins can be replaced independently of one another.

13. The test device of claim 11, wherein the detachable members of the housing comprise an upper housing member and a lower housing member that are detachably connected to each other, the upper housing member having guide openings extending therethrough, and the lower housing member having through-holes aligned with the guide openings, respectively, the springs of the pogo pins being received in the through-holes of the lower housing member and the electrical contacts of the pogo pins being received in the guide openings of the upper housing member.

14. The test device of claim 8, wherein the housing comprises detachable members between which the pogo pins are interposed such that the pogo pins can be replaced individually when the members of the housing are detached from one another.

15. The test device of claim 14, wherein the springs of the pogo pins bear against bottom surfaces of the plungers of the pogo pins, respectively, without being mechanically attached thereto, whereby the electrical contact and the spring of each of the pogo pins can be replaced independently of one another when the members of the housing are detached from one another.

16. The test device of claim 14, wherein the detachable members of the housing comprise an upper housing member and a lower housing member that are detachably connected to each other, the upper housing member having guide openings extending therethrough, and the lower housing member having through-holes aligned with the guide openings, respectively, the springs of the pogo pins being received in the through-holes of the lower housing member, and the electrical contacts of the pogo pins being received in the guide openings of the upper housing member.

17. The test device of claim 16, wherein the plunger of each of the pogo pins is received in a respective guide opening of the upper housing member, the plunger has an upper portion to which the contact pad of the pogo pin is attached and a lower portion from which the spring of the pogo pin extends, the diameter of the lower portion of the plunger being greater than the diameter of the upper portion of the plunger, and the respective guide opening of the upper housing member having upper and lower portions, the lower portion of the respective guide opening having a diameter that is substantially the same as that of the lower portion of the plunger of the pogo pin and greater than that of the upper portion of the plunger, and the upper portion of the respective guide opening having a diameter that is substantially the same as that of the upper portion of the plunger and smaller than that of the lower portion of the plunger.

18. The test device of claim 17, wherein the springs of the pogo pins are press-fitted to the lower housing member within the through-holes of the lower housing member.
